(19) United States
(12) Patent Application Publication
(10) Pub. No.: US 2024/0297286 A1
(43) Pub. Date: Sep. 5, 2024

(54) METHOD FOR PRODUCING AN OPTOELECTRONIC COMPONENT, AND OPTOELECTRONIC COMPONENT

(71) Applicant: ams-OSRAM International GmbH, Regensburg (DE)

(72) Inventors: Daniel DIETZE, Regensburg (DE); Christian BETTHAUSEN, Lappersdorf (DE); Martin HAUSHALTER, Regensburg (DE)

(21) Appl. No.: 18/573,249

(22) PCT Filed: Jun. 21, 2022
(86) PCT No.: PCT/EP2022/066817

§ 371 Date: Dec. 21, 2023

(30) Foreign Application Priority Data
Jun. 23, 2021 (DE) 10 2021 116 242.4

(51) Int. Cl. H01L 33/62; H01L 25/075; H01L 25/16; H01L 33/38

(52) U.S. Cl. CPC H01L 33/62; H01L 25/0753; H01L 25/167; H01L 33/38; H01L 2933/0016; H01L 2933/0066

(57) ABSTRACT

A method for producing an optoelectronic component comprises the following steps arranging a first optoelectronic semiconductor structure, which comprises a first structure carrier and an epitaxially grown first semiconductor layer sequence, on a bottom of a glass pane, the first semiconductor layer sequence being oriented with respect to the glass pane, arranging a moldable material on the bottom of the glass pane, the first optoelectronic semiconductor structure being embedded into the moldable material, removing part of the moldable material and removing the first structure carrier in order to expose the first semiconductor layer sequence, forming electrical contacts on the first semiconductor layer sequence, connecting a semiconductor element having a circuit integrated on a front face to the first semiconductor layer sequence, forming electrical component contacts on a rear face of the semiconductor element, and separating the optoelectronic component by dividing the glass pane.

The present invention relates to a method for producing an optoelectronic component, and to an optoelectronic component.

This patent application claims the priority of German patent application 10 2021 116 242.4, the content of the disclosure of which is hereby incorporated by reference.

Optoelectronic components are known in the prior art which comprise, in addition to optoelectronic semiconductor chips, further electronic semiconductor chips for activating the optoelectronic semiconductor chips.

One object of the present invention is to specify a method for producing an optoelectronic component. A further object of the present invention is to provide an optoelectronic component. These objects are achieved by a method for producing an optoelectronic component and by an optoelectronic component having the features of the independent claims. Various refinements are specified in the dependent claims.

A method for producing an optoelectronic component comprises steps of arranging a first optoelectronic semiconductor structure, which comprises a first structure carrier and an epitaxially grown first semiconductor layer sequence, on a lower side of a glass pane, wherein the first semiconductor layer sequence is oriented toward the glass pane, of arranging a molding material on the lower side of the glass pane, wherein the first optoelectronic semiconductor structure is embedded in the molding material, of removing a part of the molding material and the first structure carrier, in order to expose the first semiconductor layer sequence, of forming electrical contacts on the first semiconductor layer sequence, of connecting a semiconductor element having an integrated circuit on a front side to the first semiconductor layer sequence, wherein electrical circuit contacts of the circuit are connected to the electrical contacts of the first semiconductor layer sequence, of forming electrical component contacts on a rear side of the semiconductor element, and of separating the optoelectronic component by dividing the glass pane.

The semiconductor element used in this production method can be, for example, a complete semiconductor wafer. In this case, the wafer is divided jointly with the glass pane during the separation of the optoelectronic component. A semiconductor die is then formed by the division of the wafer, which becomes part of the optoelectronic component obtainable by the method. The semiconductor element used in the production method can also, however, be an already separated semiconductor die, for example, which has been formed by a prior division of a semiconductor wafer. In this case, only the glass pane is divided upon the separation of the optoelectronic component.

The method enables the production of an optoelectronic component having very compact outer dimensions. The lateral dimensions of the optoelectronic component obtainable by this method can correspond to those of the individual semiconductor die. The thickness of the optoelectronic component obtainable by the method can be less than 1 mm and can even be less than 400 μm. This is achieved, in particular, in that a carrier glass formed during the division of the glass pane is used as a supporting element of the optoelectronic component, so that no further supporting elements are necessary. A further advantage is that the method enables a use of different optoelectronic semiconductor structures. The polarity of the epitaxially grown semiconductor layer sequence can be arbitrary here.

In one embodiment of the method, the semiconductor element is thinned to a thickness of less than 300 μm, in particular to a thickness of less than 100 μm, before the formation of the component contacts. The semiconductor element can be thinned, for example, to a thickness of approximately 50 μm. A low overall thickness of the optoelectronic component obtainable by the method is thus advantageously enabled. The thinning of the semiconductor element to such a low thickness is made possible in that the semiconductor die is supported in the finished optoelectronic component by the carrier glass formed by the division of the glass pane.

In one embodiment of the method, the formation of the component contacts comprises an application of through contacts extending through the semiconductor element. The through contacts advantageously enable electrical contacting of the integrated circuit on the front side of the semiconductor element and the first semiconductor layer sequence via the component contacts formed on the rear side of the semiconductor element.

In one embodiment of the method, the semiconductor element is a wafer. The wafer is divided during the separation of the optoelectronic component so that a semiconductor die is formed. A parallel production of a plurality of identical optoelectronic components by processing on the wafer level is thus advantageously enabled. The use of a complete wafer advantageously also permits particularly precise positioning of the wafer in relation to the first semiconductor layer sequence.

In another embodiment of the method, the semiconductor element is a semiconductor die. It is possible here to place multiple identical semiconductor dies adjacent to one another in order to produce multiple identical optoelectronic components simultaneously in this way. The use of an already separated semiconductor die simplifies the separation of the optoelectronic component, since in this case only the glass pane has to be divided.

In one embodiment of the method, electrically conductive connections are arranged at outer edges of the semiconductor die. The electrically conductive connections are connected to the component contacts. These electrically conductive connections also advantageously enable electrical contacting of the integrated circuit on the front side of the semiconductor element and the first semiconductor layer sequence via the electrical component contacts formed on the rear side of the semiconductor element. The electrically conductive connections at the outer edges of the semiconductor die can be applied additionally or alternatively to through contacts extending through the semiconductor element.

In one embodiment of the method, the formation of the component contacts comprises applying a rewiring layer to the rear side of the semiconductor element. The rewiring layer can produce, for example, contacts between a contact grid on the rear side of the semiconductor element and the integrated circuit on the front side of the semiconductor element.

In one embodiment of the method, the formation of the component contacts comprises arranging solder balls on the rear side of the semiconductor element. The solder balls can form a ball grid array, for example, and enable surface mounting of the optoelectronic component obtainable by the method.

In one embodiment of the method, a second optoelectronic semiconductor structure is arranged on the lower side of the glass pane adjacent to the first optoelectronic semiconductor structure. The second optoelectronic semiconductor structure comprises a second semiconductor layer sequence. The optoelectronic component is separated so that it comprises the first semiconductor layer sequence and the second semiconductor layer sequence. The first semiconductor layer sequence and the second semiconductor layer sequence can be designed, for example, to emit light at different wavelengths. The optoelectronic component obtainable by the method can also comprise more than two semiconductor layer sequences, for example, three semiconductor layer sequences which are designed to emit light at wavelengths from the red, the green, and the blue spectral range. In this case, the optoelectronic component obtainable by the method can be designed to emit light having adjustable light color. One advantage of the optoelectronic component obtainable by the method is that the first semiconductor layer sequence and the second semiconductor layer sequence can be arranged very closely adjacent to one another. The light emitted by the optoelectronic component can then only comprise a minor dependence on angle and position.

In one embodiment of the method, a further optoelectronic semiconductor structure is arranged on the lower side of the glass pane adjacent to the first optoelectronic semiconductor structure. The further optoelectronic semiconductor structure comprises a further semiconductor layer sequence. During the separation of the optoelectronic component, a further optoelectronic component is formed which comprises the further semiconductor layer sequence. The method thus advantageously enables a parallel production of a plurality of identical optoelectronic components.

In one embodiment of the method, the first optoelectronic semiconductor structure is arranged on the lower side of the glass pane by glass-on-glass bonding or using a transparent polymer adhesion layer or a transparent adhesive layer. This method advantageously enables a reliable connection of the first optoelectronic semiconductor structure to the glass pane.

In one embodiment of the method, a filler material is arranged on the molding material before the connection of the semiconductor element to the first semiconductor layer sequence. The filler material is enclosed between the semiconductor element and the molding material. Additional stabilization of the optoelectronic component obtainable by the method is thus advantageously achieved. The filler material can also be used to protect the first semiconductor layer sequence from damage due to external effects.

In one embodiment of the method, the semiconductor element is connected to the first semiconductor layer sequence by soldering, gold-on-gold bonding, or by means of a conductive adhesive. This method advantageously enables a production of a reliable electrical connection between the electrical circuit contacts of the circuit and the electrical contacts of the first semiconductor layer sequence.

An optoelectronic component comprises a carrier glass, the semiconductor die having an integrated circuit on a front side, and a first semiconductor layer sequence, which is arranged on a lower side of the carrier glass facing toward the front side of the semiconductor die. Electrical contacts of the first semiconductor layer sequence are directly connected to electrical circuit contacts of the circuit. Electrical component contacts of the optoelectronic component are arranged on a rear side of the semiconductor die.

This optoelectronic component can advantageously comprise extremely compact outer dimensions. Lateral dimensions of the optoelectronic component can correspond to those of the semiconductor die here. The thickness of the optoelectronic component can be less than 1 mm, in particular even less than 400 μm. This can be made possible in that the carrier glass is the only supporting component of the optoelectronic component.

In one embodiment of the optoelectronic component, the first semiconductor layer sequence is an LED layer sequence. The optoelectronic component can be designed to emit electromagnetic radiation, for example, visible light. The optoelectronic component can also comprise one or more further semiconductor layer sequences adjacent to the first semiconductor layer sequence, which can also be designed as LED layer sequences, for example. In this case, the optoelectronic component can be designed to emit light having adjustable light color.

In one embodiment of the optoelectronic component, the first semiconductor layer sequence is embedded in a molding material arranged on the lower side of the carrier glass. The molding material can be made reflective, for example. The molding material can thus advantageously reflect light emitted by the first semiconductor layer sequence in the lateral direction.

In one embodiment of the optoelectronic component, the circuit is designed to control the first semiconductor layer sequence. The activation can take place here, for example, so that the first semiconductor layer sequence emits light having a desired intensity. The activation can also take place, for example, in dependence on a temperature of the first semiconductor layer sequence.

In one embodiment of the optoelectronic component, the circuit comprises a photodiode, which is provided to detect light emitted by the first semiconductor layer sequence. This advantageously enables an intensity of the light emitted by the first semiconductor layer sequence to be ascertained. This can also advantageously enable a change of the intensity of the emitted light to be compensated for.

In one embodiment of the optoelectronic component, the circuit comprises a temperature sensor, which is provided to ascertain the temperature of the first semiconductor layer sequence. Ascertaining the temperature of the first semiconductor layer sequence can advantageously enable overheating of the first semiconductor layer sequence to be prevented and/or a temperature-dependent change of a light color of the light emitted by the first semiconductor layer sequence to be compensated for.

In one embodiment of the optoelectronic component, a light-reflecting layer is arranged on the front side of the semiconductor die. Light emitted by the first semiconductor layer sequence in the direction of the front side of the semiconductor die is thus advantageously reflected at the front side of the semiconductor die.

In one embodiment of the optoelectronic component, the carrier glass comprises a thickness of less than 1000 μm, in particular a thickness of less than 500 μm. In this variant, the semiconductor die comprises a thickness of less than 300 μm, in particular a thickness of less than 100 μm. In this variant, the first semiconductor layer sequence comprises a thickness of less than 50 μm, in particular a thickness of less than 30 μm. For example, the carrier glass can comprise a thickness of approximately 300 μm. The semiconductor die can comprise, for example, a thickness of approximately 50 μm. The first semiconductor layer sequence can comprise, for example, a thickness of approximately 10 μm. The entire optoelectronic component can thus advantageously comprise an extremely low thickness, which is less than 400 μm, for example.

The above-described properties, features, and advantages of the invention and the manner in which they are achieved will become clearer and more comprehensible in conjunction with the following description of the exemplary embodiments, which are explained in more detail in conjunction with the drawings. In the respective schematic figures

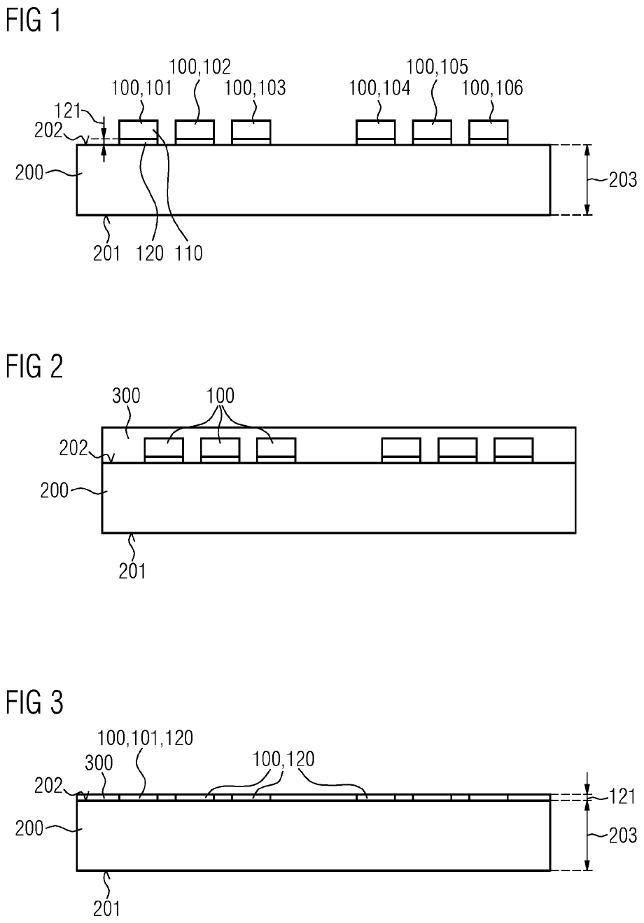

FIG. 1 shows a glass pane having semiconductor structures arranged on a lower side;

FIG. 2 shows the glass pane after the embedding of the semiconductor structures in a molding material;

FIG. 3 shows the glass pane after a removal of structure carriers of the semiconductor structures and a part of the molding material;

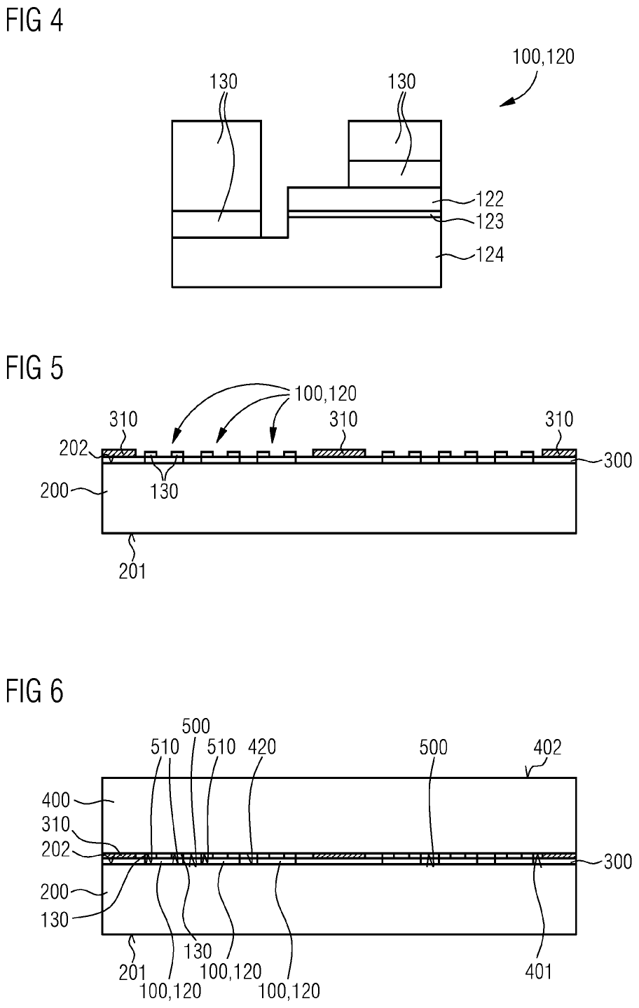

FIG. 4 shows a semiconductor layer sequence of one of the semiconductor structures;

FIG. 5 shows the glass pane having electrical contacts formed on the semiconductor layer sequences;

FIG. 6 shows the glass pane after connection of a wafer to the semiconductor layer sequences;

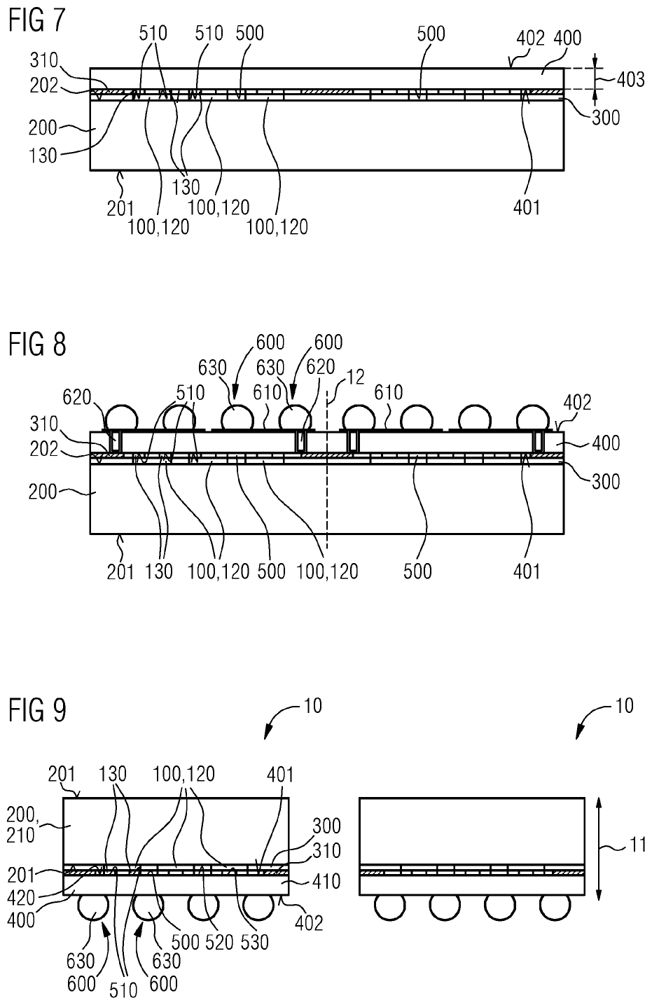

FIG. 7 shows the glass pane, the semiconductor layer sequences, and the wafer after thinning of the wafer;

FIG. 8 shows the glass pane, the semiconductor layer sequences, and the wafer after application of electrical component contacts;

FIG. 9 shows two optoelectronic components formed by dividing the glass pane and the wafer; and

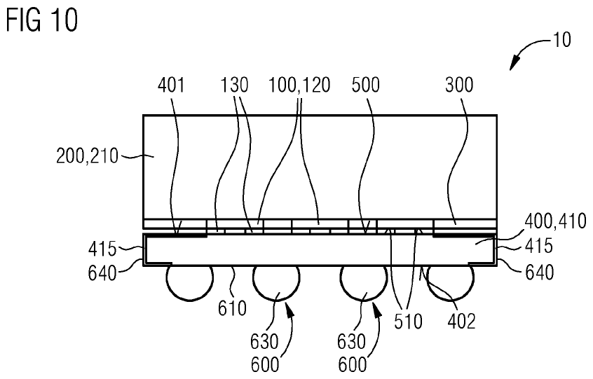

FIG. 10 shows another variant of an optoelectronic component.

FIG. 1 shows a schematic side view in section of a glass pane 200. The glass pane 200 can be designed, for example, as a glass wafer, for example, as a glass wafer having a diameter of 8 inches. The glass pane 200 comprises an upper side 201 and a lower side 202 opposite to the upper side 201, which are both made planar. The glass pane 200 comprises a thickness 203 measured from the upper side 201 to the lower side 202. It is expedient if the thickness 203 is less than 1000 μm, in particular even less than 500 μm. The thickness 203 of the glass pane 200 can be, for example, 300 μm.

Multiple optoelectronic semiconductor structures 100 have been arranged on the lower side 202 of the glass pane 200. In the example illustrated in FIG. 1 and the following figures, the optoelectronic semiconductor structures 100 arranged on the lower side 202 of the glass pane 200 comprise a first optoelectronic semiconductor structure 100, 101, a second optoelectronic semiconductor structure 100, 102, a third optoelectronic semiconductor structure 100, 103, a fourth optoelectronic semiconductor structure 100, 104, a fifth optoelectronic semiconductor structure 100, 105, and a sixth optoelectronic semiconductor structure 100, 106. In this example, the optoelectronic semiconductor structures 100 are provided for producing two optoelectronic components, which each comprise three optoelectronic semiconductor structures 100. The first optoelectronic semiconductor structure 100, 101, the second optoelectronic semiconductor structure 100, 102, and the third optoelectronic semiconductor structure 100, 103 are provided jointly for producing a first optoelectronic component. The fourth optoelectronic semiconductor structure 100, 104, the fifth optoelectronic semiconductor structure 100, 105, and the sixth optoelectronic semiconductor structure 100, 106 are provided jointly for producing a second optoelectronic component. However, it is also possible to provide only one, two, or more than three optoelectronic semiconductor structures 100 per optoelectronic component. It is also possible to arrange optoelectronic semiconductor structures 100 for only one optoelectronic component or for more than two optoelectronic components on the lower side 202 of the glass pane 200. In this case, the optoelectronic semiconductor structures 100 for the individual optoelectronic components can be arranged, for example, in the form of a matrix on the lower side 202 of the glass pane 200.

It is expedient if the sets of optoelectronic semiconductor structures 100 provided for producing an optoelectronic component are each designed identically. In the illustrated example, the first optoelectronic semiconductor structure 100, 101 is therefore designed like the fourth optoelectronic semiconductor structure 100, 104. The second optoelectronic semiconductor structure 100, 102 is designed like the fifth optoelectronic semiconductor structure 100, 105. The third optoelectronic semiconductor structure 100, 103 is designed like the sixth optoelectronic semiconductor structure 100, 106.

Each optoelectronic semiconductor structure 100 comprises a structure carrier 110 and a semiconductor layer sequence 120 produced on the structure carrier 110 by epitaxial growth. The semiconductor layer sequences 120 of the optoelectronic semiconductor structures 100 can be designed, for example, as LED layer sequences. The optoelectronic semiconductor structures 100 provided for producing an optoelectronic component can differ from one another here. In the example shown in the figures, the semiconductor layer sequence 120 of the first optoelectronic semiconductor structure 100, 101 is designed for emitting light having blue light color, the semiconductor layer sequence 120 of the second optoelectronic semiconductor structure 100, 102 is designed for emitting light from the green spectral range, and the semiconductor layer sequence 120 of the third optoelectronic semiconductor structure 100, 103 is designed for emitting light from the red spectral range. The semiconductor layer sequences 120 of the optoelectronic semiconductor structures 100 could also be, for example, laser layer sequences or other layer sequences designed for emitting electromagnetic radiation. The semiconductor layer sequences 120 of some or all optoelectronic semiconductor structures 100 could also be designed to detect electromagnetic radiation.

The optoelectronic semiconductor structures 100 have been arranged on the lower side 202 of the glass pane 200 such that the semiconductor layer sequences 120 are each oriented toward the glass pane 200. The optoelectronic semiconductor structures 100 can have been fastened here, for example, by glass-on-glass bonding or using a transparent polymer adhesion layer or a transparent adhesive layer to the lower side 202 of the glass pane 200. Glass-on-glass bonding can be carried out, for example, in that initially a layer of SiO₂ is arranged on the side of the semiconductor layer sequence 120 facing away from the structure carrier 110 and planarized.

This layer is then activated, for example, by cleaning with hydrofluoric acid and treatment with an oxygen plasma. The optoelectronic semiconductor structure 100 is then bonded via this layer on the lower side 202 of the glass pane 200 and the bond is heated. A transparent polymer adhesion layer or a transparent adhesive layer can have been applied to the lower side 202 of the glass pane 200, for example, by spin coating, before the optoelectronic semiconductor structures 100 are arranged on the lower side 202 of the glass pane 200. The arrangement of the optoelectronic semiconductor structures 100 on the glass pane 200 can be carried out, for example, by a pick and place method or by transfer printing.

FIG. 2 shows a schematic sectional side view of the glass pane 200 and the optoelectronic semiconductor structures 100 in a processing state chronologically following the illustration of FIG. 1.

A molding material 300 has been arranged on the lower side 202 of the glass pane 200. The optoelectronic semiconductor structures 100 have been embedded in the molding material 300 here. The molding material 300 completely encloses the optoelectronic semiconductor structures 100 here and in the illustrated example also covers the rear sides of the structure carriers 110 facing away from the semiconductor layer sequences 120. However, it is also conceivable that the structure carriers 110 of the optoelectronic semiconductor structures 100 are only partially covered by the molding material 300.

The molding material 300 can comprise, for example, an epoxy. It is expedient if the molding material 300 is made reflective. For this purpose, the molding material 300 can comprise, for example, a reflective filler, for example, TiO₂. The molding material 300 can have been arranged, for example, by a molding method on the lower side 202 of the glass pane 200.

FIG. 3 shows a schematic sectional side view of the glass pane 200 and the components arranged on its lower side 202 in a processing state chronologically following the illustration of FIG. 2.

The molding material 300 previously arranged on the lower side 202 of the glass pane 200 has been partially removed again. In addition, the structure carriers 110 of the optoelectronic semiconductor structures 100 have been removed here, so that the semiconductor layer sequences 120 of the optoelectronic semiconductor structures 100 have been exposed. Therefore, in the processing stage shown in FIG. 3, only the semiconductor layer sequences 120 of the optoelectronic semiconductor structures 100 embedded in a residue of the molding material 300 remain on the lower side 202 of the glass pane 200. The molding material 300 fills the gaps between the semiconductor layer sequences 120 of the individual optoelectronic semiconductor structures 100 here.

The removal of the molding material 300 and the structure carriers 110 of the optoelectronic semiconductor structures 100 can have been carried out, for example, by a grinding and planarizing process.

The semiconductor layer sequences 120 remaining on the lower side 202 of the glass pane 200 and the molding material 300 remaining on the lower side 202 comprise a thickness 121 measured in the direction perpendicular to the lower side 202. The thickness 121 can be less than 50 μm, in particular also less than 30 μm. For example, the thickness 121 can be approximately 10 μm.

FIG. 4 shows a schematic sectional side view of the semiconductor layer sequence 120 of one of the optoelectronic semiconductor structures 100. The semiconductor layer sequence 120 comprises a first doped area 122 and a second doped area 124. An active layer 123 is formed between the first doped area 122 and the second doped area 124. The first doped area 122 can be, for example, an n-doped area. The second doped area 124 can be, for example, a p-doped area. The active layer 123 can be formed, for example, as a sequence of quantum wells.

In a processing step chronologically following the illustration of FIG. 3, electrical contacts 130 have been formed on the semiconductor layer sequence 120. One of the electrical contacts 130 contacts the first doped area 122, while a further electrical contact 130 contacts the second doped area 124. The formation of the electrical contacts 130 can have been carried out, for example, by etching and sputtering processes and/or by other deposition methods. The electrical contacts 130 can comprise gold, for example.

FIG. 5 shows a schematic sectional side view of the glass pane 200 and the semiconductor layer sequences 120 in a processing stage chronologically following the illustration of FIG. 3.

Electrical contacts 130 have been formed in the above-described manner on the semiconductor layer sequences 120 of all optoelectronic semiconductor structures 100. The electrical contacts 130 protrude slightly above the level of the molding material 300 in the direction oriented perpendicular to the lower side 202 of the glass pane 200. In the example shown in FIG. 5, a filler material 310 has been arranged in at least some areas on the molding material 300 to equalize this height difference. The filler material 310 comprises a thickness here corresponding to the height of the electrical contacts 130. For this purpose, the filler material 310 can initially have been applied with greater thickness and then thinned, for example. Providing the filler material 310 can alternatively also be omitted.

FIG. 6 shows a schematic sectional side view of a processing stage chronologically following FIG. 5.

A wafer 400 having a front side 401 has been provided. The wafer 400 expediently comprises a diameter which corresponds to the diameter of the glass pane 200. For example, the wafer 400 can comprise a diameter of 8 inches. The wafer 400 is a semiconductor wafer and comprises one or more integrated circuits 500 on its front side 401. The wafer 400 comprises one integrated circuit 500 per optoelectronic component to be produced here, in the example shown in the figures thus two circuits 500. The circuits 500 comprise electrical circuit contacts 510, which can comprise gold, for example, arranged at the front side 401 of the wafer 400.

The wafer 400 has been connected to the semiconductor layer sequences 120 arranged on the glass pane 200, in that the electrical circuit contacts 510 of the circuits 500 have been directly connected to the electrical contacts 130 of the semiconductor layer sequences 120. In this case, the front side 401 of the wafer 400 was thus oriented in the direction toward the glass pane 200. The connection of the electrical circuit contacts 510 of the circuits 500 of the wafer 400 to the electrical contacts 130 of the semiconductor layer sequences 120 can have been carried out, for example, by soldering, by gold-on-gold bonding, or using a conductive adhesive.

The filler material 310 arranged on the molding material 300 has been enclosed between the wafer 400 and the molding material 300. The space remaining between the molding material 300 and the wafer 400 is thus at least partially filled by the filler material 310 and can thus also be partially or completely sealed. The filler material 310 can also be omitted, however. In this case, a small distance can remain between the wafer 400 and the molding material 300.

FIG. 7 shows a schematic sectional side view of the glass pane 200, the semiconductor layer sequence 120, and the wafer 400 in a processing stage chronologically following the illustration of FIG. 6.

The wafer 400 has been thinned to a reduced thickness 403 starting from a rear side 402 of the wafer 400 opposite to the front side 401. The thickness 403 is measured in the direction perpendicular to the front side 401 of the wafer 400 and is expediently less than 300 μm. The thickness 403 can also be less than 100 μm. For example, the thickness 403 can be approximately 50 μm. The thinning of the wafer 400 can be carried out by grinding, for example.

FIG. 8 shows a schematic sectional side view of the glass pane 200, the semiconductor layer sequences 120, and the wafer 400 in a processing stage chronologically following the illustration of FIG. 8.

Electrical component contacts 600 have been formed on the rear side 402 of the wafer 400. For this purpose, initially through contacts 620 have been applied, which extend through the wafer 400 and enable electrical contacting of the integrated circuits 500 on the front side 401 in the wafer 400 from the rear side 402 of the wafer 400. A rewiring layer 610 has then been formed on the rear side 402 of the wafer 400. The rewiring layer 610 is designed as a planar metallization and establishes electrically conductive connections to the previously applied through contacts 620. Finally, solder balls 630 have been arranged on the rear side 402 of the wafer 400. The solder balls 630 can also be referred to as solder beads and can be arranged, for example, as a regular grid (ball grid array). The solder balls 630 establish electrically conductive connections to the circuits 500 of the wafer 400 via the rewiring layer 610 and the through contacts 620, by which the electrical component contacts 600 are formed. However, it is also possible to design the electrical component contacts 600 differently.

FIG. 9 shows a schematic side view of two optoelectronic components 10 formed from the arrangement shown in FIG. 8. The optoelectronic components 10 have been separated by dividing the glass pane 200 and the wafer 400 in a separating area 12. The separation of the optoelectronic components 10 has been carried out so that one of the optoelectronic components 10 comprises the semiconductor layer sequences 120 of the first optoelectronic semiconductor structure 100, 101, the second optoelectronic semiconductor structure 100, 102, and the third optoelectronic semiconductor structure 100, 103, while the other optoelectronic component 10 comprises the semiconductor layer sequences 120 of the fourth optoelectronic semiconductor structure 100, 104, the fifth optoelectronic semiconductor structure 100, 105, and the sixth optoelectronic semiconductor structure 100, 106.

Each optoelectronic component 10 comprises a carrier glass 210 formed by dividing the glass pane 200, the upper side 201 and lower side 202 of which are formed by the upper side 201 and the lower side 202 of the glass pane 200 and the thickness 203 of which corresponds to the thickness 203 of the glass pane 200. In addition, each optoelectronic component 10 comprises a semiconductor die 410 formed by dividing the wafer 400, which has one of the integrated circuits 500 in each case. The front side 401 and rear side 402 of each semiconductor die 410 are formed by the front side 401 and the rear side 402 of the wafer 400. The thickness 403 of the semiconductor die 410 corresponds to the thickness 403 of the wafer 400.

In each optoelectronic component 10, the integrated circuit 500 on the front side 401 of the respective semiconductor die 410 is provided to control the semiconductor layer sequences 120 of the optoelectronic component 10. The circuit 500 can be designed here, for example, to control the semiconductor layer sequences 120 of the optoelectronic component 10 so that the optoelectronic component 10 emits light having an adjustable light color.

The circuit 500 can comprise one or more photodiodes 520. For example, one photodiode 520 can be provided per semiconductor layer sequence 120 of the optoelectronic component 10, so that each semiconductor layer sequence 120 is assigned one photodiode 520. This photodiode 520 can be provided, for example, to detect light emitted from the assigned semiconductor layer sequence 120. This can enable the circuit 500 to take into consideration a light color and/or an intensity of the electromagnetic radiation emitted by the semiconductor layer sequences 120 in the activation of the semiconductor layer sequences 120. It is expedient in this case if the photodiode 520 assigned to a semiconductor layer sequence 120 is arranged in each case as close as possible to the semiconductor layer sequence 120.

The circuit 500 can comprise one or more temperature sensors 530. For example, one temperature sensor 530 can be provided per semiconductor layer sequence 120 of the optoelectronic component 10, so that one temperature sensor 530 is assigned to each semiconductor layer sequence 120. The respective temperature sensor 530 can be provided to determine a temperature of the respective semiconductor layer sequence 120 in order to avoid overheating of the respective semiconductor layer sequence 120 or be able to compensate for a temperature-dependent change of the emission properties of the semiconductor layer sequence 120.

If the semiconductor layer sequences 120 of the optoelectronic components 10 are designed as light-emitting semiconductor layer sequences, electromagnetic radiation emitted by the semiconductor layer sequences 120 can be emitted in operation of the optoelectronic components 10 through the carrier glass 210 at the upper side 201 of the carrier glass 210. Electromagnetic radiation emitted by the semiconductor layer sequences 120 in the direction of the front side 401 of the respective semiconductor die 410 can be reflected at the front side 401 of the semiconductor die 410. For this purpose, the front side 401 of the semiconductor die 410 can comprise a light-reflective layer 420, which is expediently already provided at the front side 401 of the wafer 400. The light-reflective layer 420 can be designed, for example, as a metallic coating or as a spin-coated reflective film. The light-reflective layer 420 can also be designed as a dielectric mirror.

The optoelectronic components 10 comprise a thickness 11 in the direction perpendicular to the upper side 201 of the carrier glass 210 without the solder balls 630. The thickness 11 can be less than 400 μm, for example. The lateral dimensions of the optoelectronic components 10 correspond to those of the semiconductor die 410 of the optoelectronic components 10 and can be, for example, approximately 1.5 mm×1 mm.

FIG. 10 shows a schematic side view of an alternative variant of an optoelectronic component 10. The variant of the optoelectronic component 10 shown in FIG. 10 corresponds, except for the differences described hereinafter, to the variant of the optoelectronic component 10 shown in FIG. 9 and can be produced by the above-described method, wherein the differences explained hereinafter are to be taken into consideration.

In the variant of the optoelectronic component 10 shown in FIG. 10, the electrical component contacts 600 are not formed having through contacts 620 extending through the semiconductor die 410. Instead, in the variant of the optoelectronic component 10 shown in FIG. 10, outer edges 415 of the semiconductor die 410 formed by dividing the wafer 400 comprise electrically conductive connections 640, which electrically conductively connect solder balls 630 arranged on the rear side 402 of the semiconductor die 410 via the rewiring layer 610 to the integrated circuit 500 at the front side 401 of the semiconductor die 410. The electrically conductive connections 640 are arranged after the dividing of the wafer 400 on the outer edges 415 formed by the dividing of the wafer 400 of the semiconductor die 410 obtained by dividing the wafer 400.

In the above-described production method, a complete wafer 400 has been connected to the semiconductor layer sequences 120 arranged on the glass pane 200 (FIG. 6). In a later method step, the wafer 400 has been divided during the separation of the optoelectronic components (FIG. 9). Each optoelectronic component 10 formed here comprises a semiconductor die 410 formed by dividing the wafer 400, which comprises in each case one of the integrated circuits 500.

Alternatively, the described production method can be carried out so that already separated semiconductor dies 410 each having one integrated circuit 500 on the front side can be connected to the semiconductor layer sequences 120 arranged on the glass pane 200, in that the electrical circuit contacts 510 of the circuits 500 are directly connected to the electrical contacts 130 of the semiconductor layer sequences 120. These semiconductor dies 410 can be formed, for example, by prior division of the wafer 400. The further processing can take place similarly to the above-described method, wherein only the glass pane 200 still has to be divided during the separation of the optoelectronic components 10, however.

In general terms, the described production method can thus be carried out using a semiconductor element which is either a complete wafer 400 or an already separated semiconductor die 410. The semiconductor element 400, 410 comprises at least one integrated circuit 500 at a front side 401.

If an already separated semiconductor die 410 is used as a semiconductor element, it can already comprise a thickness 403 reduced in relation to the wafer 400. In this case, the thinning described on the basis of FIG. 7 can be omitted. The already separated semiconductor die 410 can also already comprise the through contacts 620 described on the basis of FIG. 8 before the connection to the first semiconductor layer sequence 120. In this case, these through contacts no longer have to be applied during the formation of the electrical component contacts 600 described on the basis of FIG. 8.

The invention was illustrated and described in more detail on the basis of the preferred exemplary embodiments. Nonetheless, the invention is not restricted to the disclosed examples. Rather, other variations can be derived therefrom by a person skilled in the art without leaving the scope of protection of the invention.

### LIST OF REFERENCE NUMERALS

10 optoelectronic component
11 thickness
12 separating area
100 optoelectronic semiconductor structure
101 first optoelectronic semiconductor structure
102 second optoelectronic semiconductor structure
103 third optoelectronic semiconductor structure
104 fourth optoelectronic semiconductor structure
105 fifth optoelectronic semiconductor structure
106 sixth optoelectronic semiconductor structure
110 structure carrier
120 semiconductor layer sequence
121 thickness
122 first doped area
123 active layer
124 second doped area
130 electrical contact
200 glass pane
201 upper side
202 lower side
203 thickness
210 carrier glass
300 molding material
310 filler material
400 wafer
401 front side
402 rear side
403 thickness
410 semiconductor die
415 outer edge
420 light-reflective layer
500 circuit
510 electrical circuit contact
520 photodiode
530 temperature sensor
600 electrical component contact
610 rewiring layer
620 through contact
630 solder ball
640 electrically conductive connection

1. A method for producing an optoelectronic component comprising the following steps:
arranging a first optoelectronic semiconductor structure, which comprises a first structure carrier and an epitaxially grown first semiconductor layer sequence, on a lower side of a glass pane, wherein the first semiconductor layer sequence is oriented toward the glass pane;
arranging a molding material on the lower side of the glass pane, wherein the first optoelectronic semiconductor structure is embedded in the molding material;
removing a part of the molding material and the first structure carrier to expose the first semiconductor layer sequence;
forming electrical contacts on the first semiconductor layer sequence;
connecting a semiconductor element having an integrated circuit on a front side to the first semiconductor layer sequence, wherein electrical circuit contacts of the circuit are connected to the electrical contacts of the first semiconductor layer sequence;
forming electrical component contacts on a rear side of the semiconductor element;
separating the optoelectronic component by dividing the glass pane.

2. The method according to claim 1,
wherein the semiconductor element is thinned to a thickness of less than 300 μm, in particular to a thickness of less than 100 μm, before the formation of the component contacts.

3. The method according to claim 1,
wherein the formation of the component contacts comprises applying through contacts extending through the semiconductor element.

4. The method according to claim 1,
wherein the semiconductor element is a wafer,
wherein the wafer is divided during the separation of the optoelectronic component so that a semiconductor die is formed.

5. The method according to claim 1,
wherein the semiconductor element is a semiconductor die.

6. The method according to claim 4,
wherein electrically conductive connections are arranged at outer edges of the semiconductor die,
wherein the electrically conductive connections are connected to the component contacts.

7. The method according to claim 1,
wherein the formation of the component contacts comprises applying a rewiring layer to the rear side of the semiconductor element.

8. The method according to claim 1,
wherein the formation of the component contacts comprises arranging solder balls on the rear side of the semiconductor element.

9. The method according to claim 1,
wherein a second optoelectronic structure is arranged adjacent to the first optoelectronic semiconductor structure on the lower side of the glass pane,
wherein the second optoelectronic semiconductor structure comprises a second semiconductor layer sequence,
wherein the optoelectronic component is separated so that it comprises the first semiconductor layer sequence and the second semiconductor layer sequence.

10. The method according to claim 1,
wherein a further optoelectronic semiconductor structure is arranged adjacent to the first optoelectronic semiconductor structure on the lower side of the glass pane,
wherein the further optoelectronic semiconductor structure comprises a further semiconductor layer sequence,
wherein during the separation of the optoelectronic component, a further optoelectronic component is formed which comprises the further semiconductor layer sequence.

11. The method according to claim 1,
wherein before the connection of the semiconductor element to the first semiconductor layer sequence, a filler material is arranged on the molding material,
wherein the filler material is enclosed between the semiconductor element and the molding material.

12. The method according to claim 1,
wherein the semiconductor element is connected to the first semiconductor layer sequence by soldering, gold-on-gold bonding, or by means of a conductive adhesive.

13. An optoelectronic component
having a carrier glass,
having a semiconductor die having an integrated circuit on a front side, and having a first semiconductor layer sequence, which is arranged on a lower side of the carrier glass facing toward the front side of the semiconductor die,
wherein electrical contacts of the first semiconductor layer sequence are directly connected to electrical circuit contacts of the circuit,
wherein electrical component contacts of the optoelectronic component are arranged on a rear side of the semiconductor die.

14. The optoelectronic component according to claim 13,
wherein the first semiconductor layer sequence is an LED layer sequence.

15. The optoelectronic component according to claim 13,
wherein the first semiconductor layer sequence is embedded in a molding material arranged on the lower side of the carrier glass.

16. The optoelectronic component according to claim 13,
wherein the circuit is designed to control the first semiconductor layer sequence.

17. The optoelectronic component according to claim 13,
wherein the circuit comprises a photodiode, which is provided to detect light emitted by the first semiconductor layer sequence.

18. The optoelectronic component according to claim 13,
wherein the circuit comprises a temperature sensor, which is provided to ascertain a temperature of the first semiconductor layer sequence.

19. The optoelectronic component according to claim 13,
wherein a light-reflective layer is arranged on the front side of the semiconductor die.

20. The optoelectronic component according to claim 13,
wherein the carrier glass comprises a thickness of less than 1000 μm, in particular a thickness of less than 500 μm,
wherein the semiconductor die comprises a thickness of less than 300 μm, in particular a thickness of less than 100 μm,
wherein the first semiconductor layer sequence comprises a thickness of less than 50 μm, in particular a thickness of less than 30 μm.
